(19) United States
(12) Patent Application Publication
(10) Pub. No.: US 2016/0336909 A1
(43) Pub. Date: Nov. 17, 2016

(54) SWITCHED CAPACITOR POWER AMPLIFIER CIRCUITS AND METHODS

(71) Applicant: QUALCOMM Incorporated, San Diego, CA (US)

(72) Inventors: Jeffrey Walling, Salt Lake City, UT (US); Wen Yuan, Salt Lake City, UT (US)

(21) Appl. No.: 14/841,489

(22) Filed: Aug. 31, 2015

Related U.S. Application Data
(60) Provisional application No. 62/161,155, filed on May 13, 2015.

(51) Int. Cl. H03F 3/00; H04B 1/16; H03F 1/56

(52) U.S. Cl. CPC H03F 3/005; H03F 1/56; H04B 1/16

(57) ABSTRACT

The present disclosure includes a switched capacitor power amplifier. In one embodiment, an SCPA includes a first capacitor array for coupling charge to a common node using first component of a signal. A second capacitor array couples charge to the common node using a second component of the signal. Relatives amplitudes between the first and second signal components may set a fine phase of the signal produced at the common node. Clock signals may be generated and used to set course phases of the signal. In one embodiment, the first and second signal components are in-phase and quadrature signals. In another embodiment, multiphase clocks are generated, and particular clocks having adjacent phases are selected to produce an output signal having a desired phase.

### CROSS REFERENCE TO RELATED APPLICATIONS

Pursuant to 35 U.S.C. §119(e), this application is entitled to and claims the benefit of the filing date of U.S. Provisional Patent Application No. 62/161,155 filed May 13, 2015, the content of which is incorporated herein by reference in its entirety for all purposes.

### BACKGROUND

The present disclosure relates to electronics, and in particular, to switched capacitor power amplifier circuits and methods.

Power amplification is required in a wide variety of electronic systems. Often, power amplification is achieved by amplifying an analog signal using an analog (or linear) power amplifier circuit. One common challenge of power amplification is efficiency and power consumption, which may vary across different applications. In particular, power is often lost in linear power amplifiers during the amplification process due to a wide variety of factors—e.g., biasing losses, resistive losses, and the like.

One common use of power amplifiers is in Radio Frequency (RF) applications, such as wireless communications. In a wireless application, RF power amplifiers typically consume a large amount of power and are a focus of interest for system power reduction. Additionally, linear power amplifiers are an obstacle for complete integration of the RF circuitry onto a single integrated circuit (e.g., a system on a chip).

In wireless communications, RF circuits are used for digital transmission of data (a digital bit stream or a digitized analog signal) between electronic systems. FIG. 1 illustrates a typical arrangement for transmitting data between two electronic systems. Electronic system 101 may include digital processing circuits 110 (e.g., a CPU and memory) for processing and storing digital data 112. Electronic system 101 may send digital data 112 to another electronic system 102 using a transmitter (Tx) 114. Transmitter 114 receives the digital data 112 and converts the digital data into an analog signal for transmission across a communication medium 103. In a wireless application, analog signals may be upconverted to radio frequency signals and then broadcast between antennas through the air, for example. Electronic system 102 includes a receiver 124 (Rx) for receiving the digital data 112. In this example, electronic systems 101 and 102 can both send data using a transmitter (Tx) and receive data using a receiver (Rx). Accordingly, electronic system 102 may also include digital processing circuits 120 for processing and storing digital data 122 that may be sent to electronic system 101 using transmitter 124, for example.

FIG. 2 illustrates an example prior art architecture for transmitting data in a wireless channel. In a wireless transmission channel, a digital data signal comprising encoded data is converted to an analog signal using a digital-to-analog converter (DAC) 201. The analog signal (or analog “baseband” signal) is then processed using a low pass filter (LPF) 202 and gain stage (Av) 203. The analog baseband signal is then shifted to a carrier frequency using up-converter 204 and a local oscillator (LO). The upconverted signal is filtered again at 205. A power amplifier 206 increases the power of the analog signal for transmission across the communication medium.

Power consumption is a significant problem in contemporary transmission systems. The rapid expansion of communication systems, such as wireless devices, has tightened the power consumption requirements of devices, and transmitters are a large source of such consumption. Traditional analog power amplifiers, for example, consume particularly large amounts of power. Improving the efficiency of such analog power amplifiers is an area of continued research.

### SUMMARY

The present disclosure includes a switched capacitor power amplifier. In one embodiment, an SCPA includes a first capacitor array for coupling charge to a common node using first component of a signal. A second capacitor array couples charge to the common node using a second component of the signal. Relatives amplitudes between the first and second signal components may set a fine phase of the signal produced at the common node. Clock signals may be generated and used to set course phases of the signal. In one embodiment, the first and second signal components are in-phase and quadrature signals. In another embodiment, multiphase clocks are generated, and particular clocks having adjacent phases are selected to produce an output signal having a desired phase.

The following detailed description and accompanying drawings provide a better understanding of the nature and advantages of the present disclosure.

### BRIEF DESCRIPTION OF THE DRAWINGS

FIG. 1 illustrates a typical arrangement for transmitting data between two electronic systems.

FIG. 2 illustrates a typical architecture for transmitting data.

FIG. 3 illustrates power amplifier circuitry according to one embodiment.

FIG. 4 illustrates examples output signals generated using I and Q components according to an embodiment.

FIG. 5 illustrates a switched capacitor power amplifier according to another embodiment.

FIG. 6 illustrates examples output signals generated using multiphase components according to an embodiment.

FIG. 7 illustrates example power amplifier circuitry according to another embodiment.

FIG. 8 illustrates an electronic power amplifier method according to an embodiment.

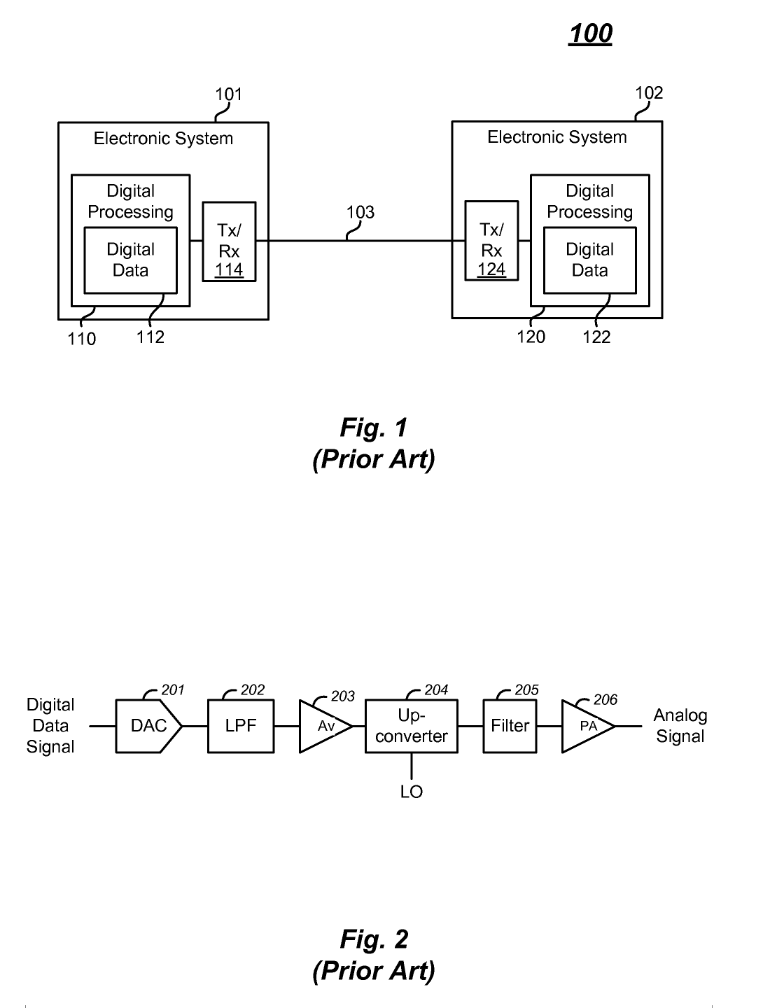

### DETAILED DESCRIPTION

In the following description, for purposes of explanation, numerous examples and specific details are set forth in order to provide a thorough understanding of the present disclosure. It will be evident, however, to one skilled in the art that the present disclosure as expressed in the claims may include some or all of the features in these examples, alone or in combination with other features described below, and may further include modifications and equivalents of the features and concepts described herein.

Features and advantages of the present disclosure include innovative switched capacitor power amplifier (SCPA) techniques. In one embodiment, components of a signal (e.g., I and Q) are coupled through different capacitor arrays (or capacitor groups) and combined on a common node shared by the capacitors. In some embodiments, coding circuits (coders) may map amplitudes of different signal components to different capacitor arrays, for example. Capacitors in each of the capacitor arrays may be selectively coupled to one or more reference voltages (e.g., one or more power supply voltages, Vdd, and ground) using a switching network. The amplitudes of the signal components may be used to control which capacitors in each capacitor array are coupled to particular power supply voltages, ground, or left open, for example. Accordingly, different signal components may be used to control corresponding capacitor arrays so that the composite signal may be generated from its' components by combining charge from different capacitor arrays on a common node. Amplitude and phase of the composite signal may be obtained from relative amplitudes of components of the signal being coupled through capacitor arrays and by controlling the time that each array couples charge to the common node (e.g., using phases of different clock signals). In one embodiment, components of the signal, such as an in-phase (I) component and quadrature (Q) component, may be coupled through an in-phase (I) capacitor array and a quadrature (Q) capacitor array and clocked using I and Q clocks so that the I and Q components may be summed in the charge domain (e.g., through I and Q capacitors using the I and Q clocks). As a result, I and Q component vectors generate a composite output signal. More generally, embodiments of the disclosure include using relative amplitudes of first and second signal components as a fine phase component of a signal to be generated. Capacitor arrays may be configured (e.g., clocked to produce outputs on a common node) at different times using clock signals with different phases, and a difference between a first clock phase and a second clock phase may correspond to a course phase component of the phase of the output signal to be generated. A plurality of clock signals with different phases may be generated and selected to generate a composite output signal with any phase, for example. I and Q signals and corresponding I and Q clock signals separated by 90 degrees are one example implementation. More broadly, additional clocks could be used with more clock phases to improve the construction of the output signal as described in more detail below.

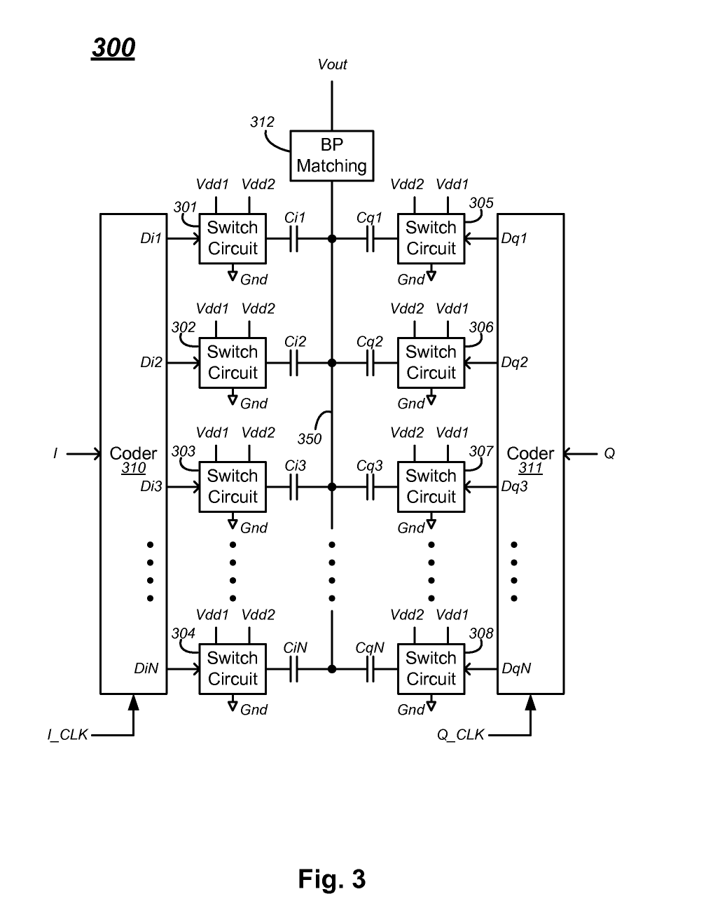

FIG. 3 illustrates power amplifier circuitry according to one embodiment. FIG. 3 illustrates an embodiment that receives digital I and Q signals and uses the digital I and Q signals to control an I capacitor array and a Q capacitor array, respectively, to combine the I and Q signal components in the charge domain to produce an output signal. Circuit 300 is an example of a switched capacitor power amplifier (SCPA). In this example, SCPA 300 includes digital coders 310 and 311 (sometimes referred to as decoders or encoders), switching circuits 301-308, capacitors Ci1-CiN and Cq1-CqN, and a bandpass matching network 312. In this example, coder 310 receives a first digital signal corresponding to the in-phase (I) component of the signal to be generated, and in accordance therewith, generates first coded digital signals Di1-DiN for driving switching circuits 301-304. Coded digital signals Di1-DiN may correspond to mapping an amplitude of the in-phase component to values of Di1-DiN required to configure capacitors Ci1-CiN to transfer charge to a common node 350 to generate a voltage level corresponding to the in-phase component amplitude. Coder 311 receives a second digital signal corresponding to the quadrature (Q) component of the signal, and in accordance therewith, generates second coded digital signals Dq1-DqN for driving switching circuits 305-308. Coded digital signals Dq1-DqN may correspond to mapping an amplitude of the quadrature component to values of Dq1-DqN required to configure capacitors Cq1-CqN to transfer charge to a common node 350 to generate a voltage level corresponding to the quadrature component amplitude.

The plurality of first coded digital signals Di1-DiN representing the in-phase component of the signal to be generated are received on a plurality of first switches in switching circuits 301-304. The plurality of first switches are configured to selectively couple a corresponding plurality of first capacitor terminals of a plurality of first capacitors Ci1-CiN between two or more reference voltages (e.g., Vdd and ground). Similarly, the plurality of second coded digital signals Dq1-DqN representing the quadrature component of the signal are received on a plurality of second switches in switching circuits 301-304. The plurality of second switches are configured to selectively couple a corresponding plurality of first capacitor terminals of a plurality of second capacitors Cq1-CqN between two or more reference voltages (e.g., Vdd and ground). In this example, switching circuits 301-308 are coupled to multiple reference voltages, including a first power supply voltage, Vdd1, a second power supply voltage, Vdd2 (e.g., Vdd2>Vdd1), and ground (Gnd). Accordingly, switching circuits 301-304 selectively couple a first capacitor terminal on each of a first group of capacitors (Ci1-CiN) between two power supply voltages (e.g., Vdd1 and Vdd2) and ground. Similarly, switching circuits 305-308 selectively couple a first capacitor terminal on each of a second group of capacitors (Cq1-CqN) between two power supply voltages (e.g., Vdd1 and Vdd2) and ground. Other embodiments may use only one power supply voltage, Vdd, and ground, or other reference voltage arrangements to switch charge to a common node 350.

More specifically, in one example embodiment, one terminal of each capacitor, Ci, in the in-phase capacitor array may be coupled to ground through a first switch, to a first power supply voltage Vdd1 through a second switch, and to a second power supply voltage Vdd2 that is greater than Vdd1 through a third switch. In-phase coded digital signals Di control the switches on Ci so that one of the first, second, or third switch is closed to transfer charge to a second terminal of Ci. Coded digital signals Di1-DiN and Dq1-DqN similarly control switches to couple a terminal of corresponding capacitors Ci1-CiN and Cq1-CqN between Vdd1 (and optionally Vdd2) and ground to couple charge to common node 350. One example implementation of a switching circuit is described in more detail below.

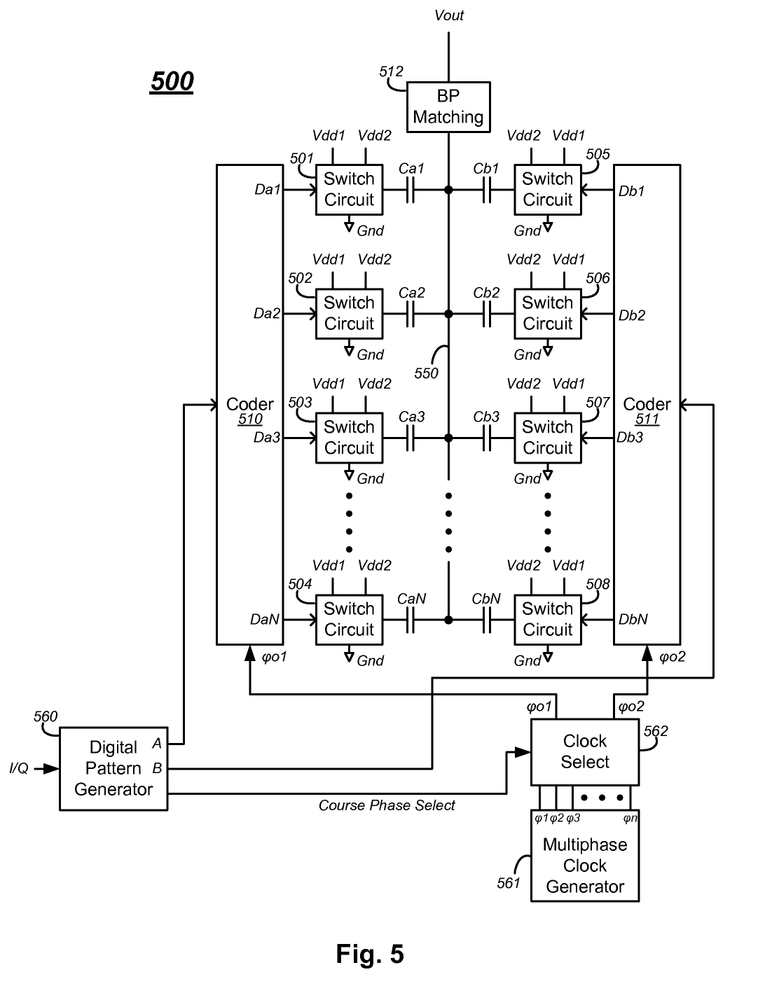

According to various embodiments, multiple clock signals with different phases may be used to configure the capacitor terminals between reference voltages at different times to produce a course phase for the signal produced on common node 350. In this example, coder 310 receives an in-phase clock I_CLK and coder 311 receives a quadrature clock Q_CLK. I_CLK and Q_CLK may be differential clocks, for example, such that I_CLK includes I_CLK and I_CLK* (the inverse of I_CLK) and Q_CLK includes Q_CLK and Q_CLK* (the inverse of Q_CLK). In the I and Q example, I_CLK is phase shifted from Q_CLK by 90 degrees (i.e., π/2). In some embodiments described in more detail below, I_CLK or Q_CLK or both may advantageously be inverted to change the course phase of the signal combined at the common node. For example, non-inverted I_CLK and non-inverted Q_CLK may be used to combine signals in the +I and +Q quadrant (e.g., course phase: 0−π/2). Inverted I_CLK and non-inverted Q_CLK may be used to combine signals in the −I and +Q quadrant (e.g., course phase: π/2−π). Inverted I_CLK and inverted Q_CLK may be used to combine signals in the −I and −Q quadrant (e.g., course phase: π−3π/2). Finally, non-inverted I_CLK and inverted Q_CLK may be used to combine signals in the +I and −Q quadrant (e.g., course phase: 3π/2−2η). This approach may be advantageously expanded to additional course phase segments in FIG. 5 below. Further, I_CLK and Q_CLK may advantageously be 50% duty cycle clocks because the I and Q signal components are processed using separate capacitor arrays, resulting in a higher output power for a given load resistance, for example.

In-phase and quadrature components may be summed in the charge domain on common node 350 in response to the coded digital signals Di and Dq configuring terminals of the capacitors between Vdd and ground. In this example, common node 350 is coupled to a bandpass matching network 312. Bandpass matching network 312 may include an inductor, for example. Accordingly, the switching capacitors and at least one inductor produce the desired output signal as the I component and Q component are summed at the common node. The LC circuit may act to filter the switching signal to produce a desired output signal.

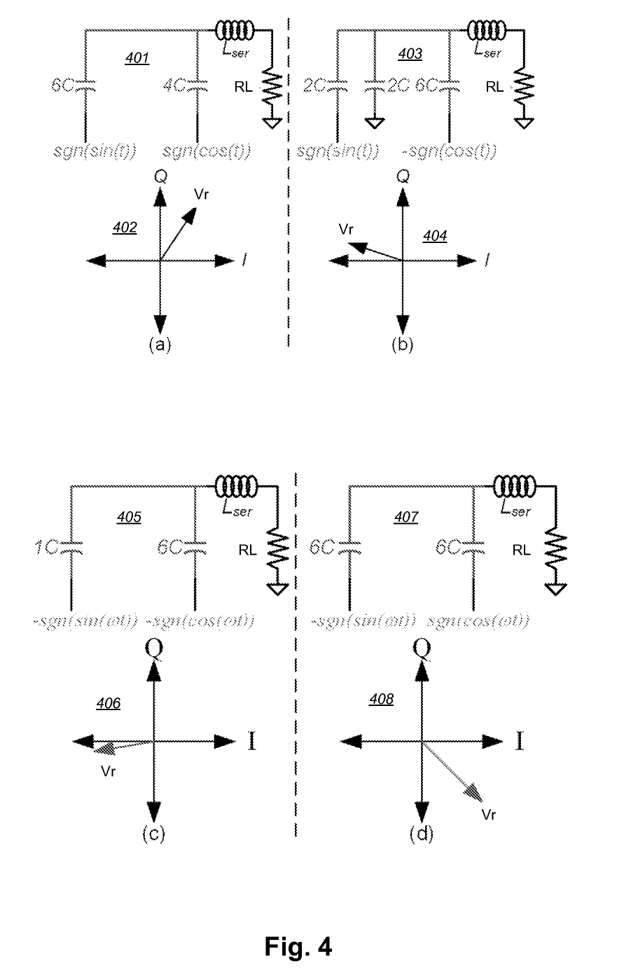

FIG. 4 illustrates example configurations of SCPA 300 in FIG. 3 and associated vectors according to an embodiment. In the following examples, the Cos(t) component corresponds to the in-phase component and the Sin(t) component corresponds to the quadrature component. A first example configuration is shown at 401 and 402. In this example, the I component is mapped (by coder 310) to activate 4 capacitors in the array. Similarly, the Q component is mapped (by coder 311) to activate 6 capacitors in the array. The sign of both the I and Q components are both positive, which may correspond to using non-inverted I and Q clocks to set a course phase between 0 and η/2. The vector summation of the I and Q components is shown at 402a. Resultant vector Vr corresponds to the output signal at the common node, which may be filtered by a series inductance, Lser, for example, and driven to a load. The load is modeled here as a load resistance RL and may be an antenna, for example.

A second example configuration is shown at 403 and 404. In this example, the Q component is mapped (by coder 311) to couple 2 capacitors to Vdd and 2 capacitors to ground. Similarly, the I component is mapped (by coder 310) to activate 6 capacitors in the array. In this example, the sign of the I component is negative and the sign of the Q component is positive, which may correspond to using an inverted I clock and a non-inverted Q clock to set a course phase between π/2−π. The vector summation of the I and Q components is shown at 404. Similar to the example shown at 401 and 402, the course phase is set by the phase of the clocks and the fine phase is set by the relative amplitudes of the I and Q components.

A third example configuration is shown at 405 and 406. In this example, the Q component is mapped (by coder 311) to couple 1 capacitor in the Q capacitor array to Vdd and the I component is mapped (by coder 310) to couple 6 capacitors in the I capacitor array to Vdd. In this example, the sign of both the I and Q components are negative, which may correspond to using inverted I and Q clocks to set a course phase between π−3π/2. The vector summation of the I and Q components is shown at 406. Similar to the example shown at 401 and 402, the course phase is set by the phase of the clocks and the fine phase is set by the relative amplitudes of the I and Q components.

A fourth example configuration is shown at 407 and 408. In this example, the I component is mapped (by coder 310) to couple 6 capacitors in the I capacitor array to Vdd and the Q component is mapped (by coder 311) to couple 6 capacitors in the Q capacitor array to Vdd. In this example, the sign of the I component is positive and the sign of the Q component is negative, which may correspond to using a non-inverted I clock and an inverted Q clock to set a course phase between 3π/2−2η. The vector summation of the I and Q components is shown at 408. Similar to the examples shown above, the course phase is set by the phase of the clocks and the fine phase is set by the relative amplitudes of the I and Q components.

FIG. 5 illustrates a switched capacitor power amplifier 500 according to another embodiment. FIG. 5 illustrates an embodiment that receives I and Q signals, for example, and generates component vectors A and B and selects particular clock signal phases to control two different capacitor arrays to combine the component vectors in the charge domain to produce an output signal. In this example, SCPA 500 includes digital coders 510 and 511, switching circuits 501-508, capacitors Ca1-CaN and Cb1-CbN, and a bandpass matching network 512. SCPA 500 further includes a digital pattern generator 560, multiphase clock generator 561, and clock selection circuit 562.

An input signal to be amplified is coupled to digital pattern generator 560. In this example, the input signal is an in-phase/quadrature signal (I/Q). Digital pattern generator 560 may analyze the input signal and determine the amplitude to be used on two different capacitor arrays as well as select clock signal phases to produce an amplified output signal. The signals produced by digital pattern generator 560 (e.g., signal A and signal B) are coupled to coders 510 and 511. Relative amplitudes of signals A and B set a fine phase. The selected clock signal phases set the course phase. In this example, the first component of the output signal, signal A, is the amplitude of the in-phase component, which may be received by coder 510. Similarly, the second component of the output signal, signal B, is the amplitude of the quadrature component, which may be received by coder 511.

Coder circuits 510-511 and switching circuits 501-508 receive the digital signals A and B corresponding to the I and Q components, respectively, of the signal to be amplified and configure first capacitor terminals of capacitors Ca1-CaN and Cb1-CbN between two or more reference voltages (e.g., Vdd1, Vdd2, and Gnd). A difference between the amplitude of signal A and the amplitude of signal B may correspond to a fine phase component of the phase of the signal to be generated on common node 550, for example.

Coder circuit 510 generates coded digital signals Da1-DaN representing the amplitude of the I component of the signal. Coder circuit 511 generates coded digital signals Db1-DbN representing the amplitude of the Q component of the signal. Coded digital signals Da1-DaN control switching circuits 501-504 to selectively coupled terminals of capacitors Ca1-CaN between Vdd1 or Vdd2 and ground, for example. Likewise, coded digital signals Db1-DbN control switching circuits 505-508 to selectively coupled terminals of capacitors Cb1-CbN between Vdd1 or Vdd2 and ground, for example. Capacitors Ca1-CaN and Cb1-CbN have second terminals coupled to common node 550 where charge from each capacitor may be combined to form a composite output signal.

In some embodiments, the phase of the output signal is further determined by selecting clock signals used to configure the capacitors. For example, digital pattern generator 560 may evaluate the signal to be transmitted and select particular clock signal phases from a plurality of clock signal phases. In this example, the quadrature (I/Q) bit pattern is analyzed by the digital pattern generator 560. Digital pattern generator 560 may determine a desired output phase and select the nearest two phases available from the multiphase clock generator 561. In the coder circuits 510 and 511, a number of capacitors from each array are triggered for switching between Vdd and ground, and the remaining capacitors may be held at ground, for example.

In this example, a multiphase clock generator circuit 561 generates multiple clocks φ1-φn having different phases. Additionally, different phases of the different clocks may differ in phase by equal phase differences (i.e., the phases of the different clocks may be uniformly separated by approximately equal phase differences). Multiphase clock generator circuit 561 may comprise a clock signal generator (e.g., a differential clock generator) and a polyphase filter (e.g., series connected RC delay circuits) or a delay locked loop (DLL) to produce multiple output phases of the clock signal with constant output amplitudes, for example. A first clock signal, φo1, and a second clock signal, φo2, are selected from the plurality of clock signals φ1-φn. The phase of the first clock signal, φo1, may be adjacent in phase to the phase of the second clock signal, φo2, for example. A difference between the first clock phase and the second clock phase may correspond to a course phase component of the phase of the signal, as further illustrated below.

The first and second clock signals are received by coder circuit 510 and coder circuit 511 to control when the configuration of the capacitors is performed. For example, an edge of the first clock signal φo1 may occur before an edge of the second clock signal φo2 so that charge coupling on capacitors Ca1-CaN is performed before charge coupling on capacitors Cb1-CbN. Similar to the I/Q implementation, the first and second clock signals φo1 and φo2 may be 50% duty cycle differential clocks, for example. For example, in the case where φo1 and φo2 are separated in phase by 90 degrees (e.g., I and Q), the I bits may cause the certain I capacitors to be switched to Vdd. As long as the I capacitors settle before the Q bits are switched, there may be is interaction between the I and Q signals as they are summed at the common node. Thus, the coder circuits and switches may be run on 50% duty cycle clocks having different phases. One advantage of this approach is that a higher output power may be achieved because the fundamental coefficient is larger than if a smaller duty cycle were used, for example. More generally, if one capacitor array settles before the other capacitor array is switched, the time difference between the edges may set a maximum speed of the system. For a multiphase system with many clock signal phases available to set the course phase, the edges may be very close together as the number of course phases increases. In some embodiments, if one capacitor array is not completely settled before the other capacitor array is switched, interaction between the two arrays may be corrected by pre-distorting the signal, for example.

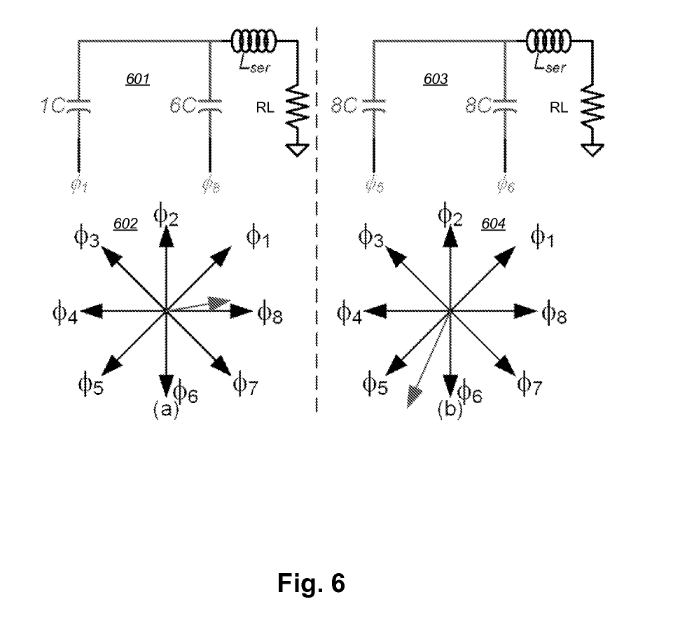

FIG. 6 illustrates example configurations of SCPA 500 in FIG. 5 and associated vectors according to an embodiment. A first example configuration is shown at 601 and 602. In this example, there are 8 clock signals with 8 different phases to choose from. The A component is clocked by φ1 and mapped (by coder 510) to activate 1 capacitor in the array. Similarly, the B component is clocked by φ8 and mapped (by coder 511) to activate 6 capacitors in the array. In this example, coder 510 is clocked with an edge before coder 511, but the opposite may be true. In other implementations, φ1 and φ2 are received by each capacitor and the decoder chooses which clock to use directly at the capacitor, which may allow for larger signal amplitudes, for example. In this example, the φ1 and φ8 clocks set a course phase between 0 and 45 degrees. The vector summation of the A and B components is shown at 602a. Resultant vector Vr corresponds to the output signal at the common node, which may be filtered by a series inductance, Lser, for example, and driven to a load. The load is modeled here as a load resistance RL and may be an antenna, for example.

A second example configuration is shown at 603 and 604. The A component is clocked by φ5 and mapped (by coder 510) to activate 8 capacitors in the array. Similarly, the B component is clocked by adjacent phase φ6 and mapped (by coder 511) to activate 8 capacitors in the array. In this example, the φ5 and φ6 clocks set a course phase between 225 degrees and 270 degrees. The vector summation of the A and B components is shown at 606a. Resultant vector Vr corresponds to the output signal at the common node.

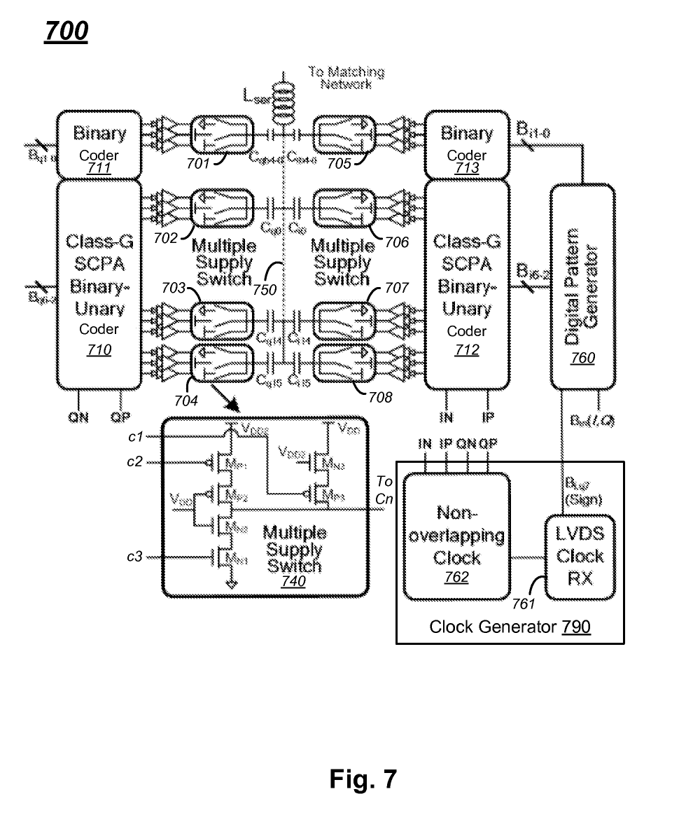

FIG. 7 illustrates one example implementation of a switched capacitor power amplifier quadrature power amplifier. In this example, SCPA 700 includes digital coders 710-712, switching circuits 701-708, binary weighted capacitors Cib4-0 and Cqb4-0, equally sized capacitors Ci0-Ci15 and Cq0-Cq15, digital pattern generator 760, and a clock generator 790 comprising a low voltage differential signal (LVDS) clock circuit 761 and a non-overlapping clock circuit 762.

I and Q digital bits Bin(I,Q) may be received by digital pattern generator 760. In one embodiment, SCPA 700 may include a clock generator 790 to detect a polarity of the in-phase component of the signal and a polarity of the quadrature component of the signal, and in accordance therewith, invert one of: (i) the first clock signal and the second clock signal, (ii) the third clock signal and the fourth clock signal, or (iii) the first clock signal, the second clock signal, the third clock signal, and the fourth clock signal. In this example, a least significant bit (LSB) from each of the I and Q signals (e.g., Bi,q7) may be used as a sign bit to determine the polarity of the clock signals, and therefore, the course phase of the output signal. The LSB sign bits are coupled to LVDS circuit 761 to generate I and Q clocks, including a positive I clock, IP, negative I clock, IN, positive Q clock, QP, and negative Q clock, QN. IP, IN, QP, and QN may be coupled through a non-overlapping clock circuit 762 to adjust the timing of the clock edges to prevent current shoot through caused by devices turning on and off at the same time, for example. IP and IN are received by coding circuits 712 and 713 and QP and QN are received by coding circuit 710 and 711 to control the time that the capacitors are configured to couple charge to the common node.

In this example, I and Q capacitor arrays comprise binary weighted capacitors and approximately equal sized capacitors. Accordingly, coding circuits for the Q component include a unary coder 710 and a binary coder 711. Similarly, coding circuits for the I component include a unary coder 712 and a binary coder 713. In this example implementation, LSBs Bi1-0 and Bq1-0 are coupled to binary coders 713 and 711, respectively, to drive binary weighted capacitors Cib4-0 and Cqb4-0. In some embodiments, one or more capacitors may be held at Vdd, for example. Additionally, digital signals Bi6-2 and Bq6-2 are translated to unary codes, such as a thermometer encoder, for example. Accordingly, certain embodiments may include both binary coders and capacitors to advantageously reduce the size of the capacitor arrays and unary coders driving equally sized capacitors to advantageously to improve the accuracy. Other embodiments may be entirely binary or entirely unary depending on the application, for example.

Coding circuits 710-713 generate coded digital signals to drive multiple supply switches 701-708. One example switching circuit is shown at 740. Coded digital signals, in this example, comprise three control bits C1, C2, and C3. Control bit C1 turns PMOS transistor MP3 ON and OFF, thereby selectively coupling Vdd through cascode transistor MN3 to one terminal of a capacitor in the array. Control bit C2 turns PMOS transistor MP1 ON and OFF, thereby selectively coupling Vdd2, which may be greater than Vdd, through cascode transistor MP2 to one terminal of a capacitor in the array. Finally, control bit C3 turns NMOS transistor MN1 ON and OFF, thereby selectively coupling ground through cascode transistor MN2 to one terminal of a capacitor in the array. Accordingly, capacitors in the arrays may be selectively coupled between ground and one or more power supply voltages to couple charge to the common node 750. In some example applications, VDD and VDD2 may be used simultaneously on different capacitors in the array, for example.

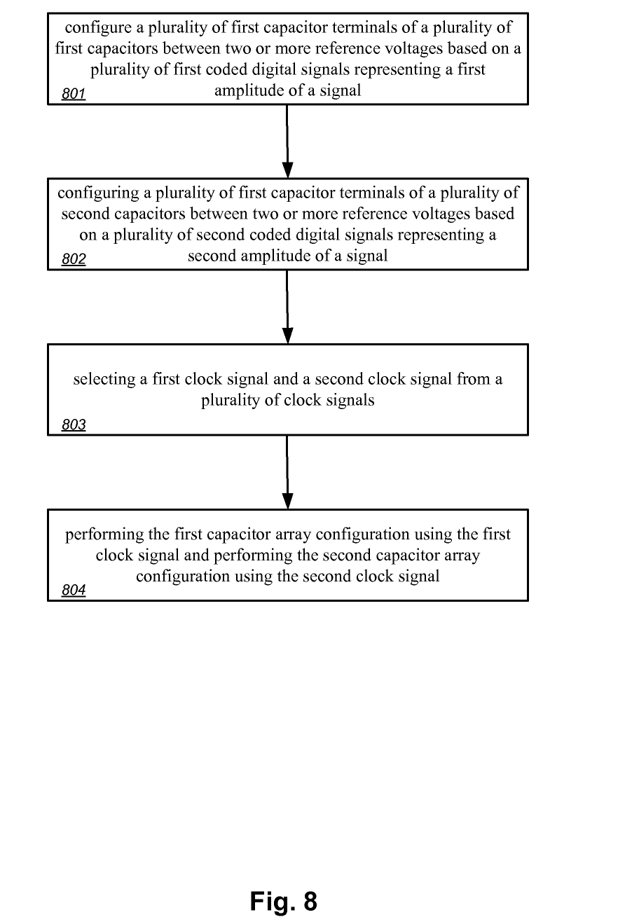

FIG. 8 illustrates an electronic power amplifier method according to an embodiment. At 801, first capacitor terminals of a plurality of first capacitors are configured between two or more reference voltages based on a plurality of first coded digital signals representing a first amplitude of a signal. The two or more reference voltage may be ground and Vdd, for example, or ground and multiple different power supply voltages. At 802, first capacitor terminals of a plurality of second capacitors are configured between two or more reference voltages based on a plurality of second coded digital signals representing a second amplitude of a signal. A difference between the first amplitude and the second amplitude may correspond to a fine phase component of a phase of the signal, for example. Second capacitor terminals of the first capacitors and second capacitor terminals of the second capacitors may be coupled to a common node, where the signal components are combined. At 803, a first clock signal and a second clock signal are selected from a plurality of clock signals. The plurality of clock signals have a plurality of different clock phases. For example, the first clock signal has a first clock phase and the second clock signal has a second clock phase. The first clock phase may be adjacent in phase to the second clock phase in the plurality of different clock phases. A difference between the first clock phase and the second clock phase may correspond to a course phase component of the phase of the signal. At 804, the configuration of the first capacitors based on the plurality of first coded digital signals is performed using the first clock signal, and the configuration of second capacitors based on the plurality of second coded digital signals is performed using the second clock signal. Accordingly, the signal is generated having the proscribed phase on the common node.

The above description illustrates various embodiments of the present disclosure along with examples of how aspects of the particular embodiments may be implemented. The above examples should not be deemed to be the only embodiments, and are presented to illustrate the flexibility and advantages of the particular embodiments as defined by the following claims. Based on the above disclosure and the following claims, other arrangements, embodiments, implementations and equivalents may be employed without departing from the scope of the present disclosure as defined by the claims.

What is claimed is:

1. An electronic power amplifier method comprising:
receiving a plurality of first coded digital signals representing an in-phase component of a signal on a plurality of first switches, wherein the plurality of first switches are configured to selectively couple a corresponding plurality of first capacitor terminals of a plurality of first capacitors between two or more reference voltages; and
receiving a plurality of second coded digital signals representing a quadrature component of the signal on a plurality of second switches, wherein the plurality of second switches are configured to selectively couple a corresponding plurality of second capacitor terminals of a plurality of second capacitors between the two or more reference voltages,
wherein a plurality of second capacitor terminals of the first capacitors and a plurality of second capacitor terminals of the second capacitors are coupled to a common node, and wherein the common node is coupled through a bandpass matching network to an output terminal.

2. The method of claim 1 further comprising generating a first clock signal corresponding to a positive in-phase component of the signal, a second clock signal corresponding to a negative in-phase component of the signal, a third clock signal corresponding to a positive quadrature component of the signal, a fourth clock signal corresponding to a negative quadrature component of the signal.

3. The method of claim 2 wherein the first clock signal, the second clock signal, the third clock signal, and the fourth clock signal each have a fifty percent duty cycle.

4. The method of claim 2 further comprising detecting a polarity of the in-phase component of the signal and a polarity of the quadrature component of the signal, and in accordance therewith, inverting one of: (i) the first clock signal and the second clock signal, (ii) the third clock signal and the fourth clock signal, or (iii) the first clock signal, the second clock signal, the third clock signal, and the fourth clock signal.

5. The method of claim 2 wherein said detecting is based on a sign bit of a first digital signal corresponding to the in-phase component of the signal and a sign bit of a second digital signal corresponding to the quadrature component of the signal.

6. The method of claim 1 wherein the bandpass matching network comprises an inductor.

7. The method of claim 1 wherein the two or more reference voltages comprise a first power supply voltage and ground.

8. The method of claim 7 wherein the two or more reference voltages further comprise a second power supply voltage greater than the first power supply voltage.

9. The method of claim 1 wherein the plurality of first capacitors comprise a first plurality of first capacitors having the same size and a second plurality of first capacitors having different sizes, wherein sizes of the second plurality of first capacitors are binary weighted, and wherein the plurality of second capacitors comprise a first plurality of second capacitors having the same size and a second plurality of second capacitors having different sizes, wherein sizes of the second plurality of second capacitors are binary weighted.

10. The method of claim 1 further comprising:
receiving a first digital signal corresponding to the in-phase component of the signal in a first coding circuit, and in accordance therewith, generating the first coded digital signals; and
receiving a second digital signal corresponding to the quadrature component of the signal in a second coding circuit, and in accordance therewith, generating the second coded digital signals.

11. The method of claim 10 wherein the first coding circuit comprises a first unary coder and a first binary coder, and wherein the second coding circuit comprises a second unary coder and a second binary coder.

12. A power amplifier circuit comprising:
a plurality of first capacitors having a plurality of first capacitor terminals and a plurality of second capacitor terminals, wherein the plurality of first capacitor terminals of the first capacitors are coupled to a plurality of first switches configured to selectively couple the plurality of first capacitor terminals of the first capacitors between two or more reference voltages in response to a plurality of first coded digital signals received by the plurality of first switches, wherein the first coded digital signals represent an in-phase component of a signal;
a plurality of second capacitors having a plurality of first capacitor terminals and a plurality of second capacitor terminals, wherein the plurality of first capacitor terminals of the second capacitors are coupled to a plurality of second switches configured to selectively couple the plurality of first capacitor terminals of the second capacitors between the two or more reference voltages in response to a plurality of second coded digital signals received by the plurality of second switches, wherein the second coded digital signals represent an quadrature component of the signal; and
a bandpass matching network, wherein an input of the bandpass matching network is coupled to a common node, and wherein the plurality of second capacitor terminals of the first capacitors are coupled to the common node, and wherein the plurality of second capacitor terminals of the second capacitors are coupled to the common node.

13. The circuit of claim 12 further comprising a clock generator to produce a first clock signal corresponding to a positive in-phase component of the signal, a second clock signal corresponding to a negative in-phase component of the signal, a third clock signal corresponding to a positive quadrature component of the signal, a fourth clock signal corresponding to a negative quadrature component of the signal.

14. The circuit of claim 13 wherein the first clock signal, the second clock signal, the third clock signal, and the fourth clock signal each have a fifty percent duty cycle.

15. The circuit of claim 13 wherein the clock generator detects a polarity of the in-phase component of the signal and a polarity of the quadrature component of the signal, and in accordance therewith, inverting one of: (i) the first clock signal and the second clock signal, (ii) the third clock signal and the fourth clock signal, or (iii) the first clock signal, the second clock signal, the third clock signal, and the fourth clock signal.

16. The circuit of claim 13 wherein said detecting is based on a sign bit of a first digital signal corresponding to the in-phase component of the signal and a sign bit of a second digital signal corresponding to the quadrature component of the signal.

17. The circuit of claim 12 wherein the plurality of first capacitors comprise a first plurality of first capacitors having the same size and a second plurality of first capacitors having different sizes, wherein sizes of the second plurality of first capacitors are binary weighted, and wherein the plurality of second capacitors comprise a first plurality of second capacitors having the same size and a second plurality of second capacitors having different sizes, wherein sizes of the second plurality of second capacitors are binary weighted.

18. The circuit of claim 12 further comprising:
a first coding circuit to receive a first digital signal corresponding to the in-phase component of the signal, and in accordance therewith, generate the first coded digital signals; and
a second coding circuit to receive a second digital signal corresponding to the quadrature component of the signal, and in accordance therewith, generating the second coded digital signals.

19. The circuit of claim 18 wherein the first coding circuit comprises a first unary coder and a first binary coder, and wherein the second coding circuit comprises a second unary coder and a second binary coder.

20. An electronic power amplifier method comprising:
configuring a plurality of first capacitor terminals of a plurality of first capacitors between two or more reference voltages based on a plurality of first coded digital signals representing a first amplitude of a signal;
configuring a plurality of first capacitor terminals of a plurality of second capacitors between two or more reference voltages based on a plurality of second coded digital signals representing a second amplitude of a signal, wherein a difference between the first amplitude and the second amplitude corresponds to a fine phase component of a phase of the signal, and wherein a plurality of second capacitor terminals of the first capacitors and a plurality of second capacitor terminals of the second capacitors are coupled to a common node;
selecting a first clock signal and a second clock signal from a plurality of clock signals, the plurality of clock signals having a plurality of different clock phases, wherein the first clock signal has a first clock phase and the second clock signal has a second clock phase and wherein the first clock phase is adjacent in phase to the second clock phase in the plurality of different clock phases, and wherein a difference between the first clock phase and the second clock phase corresponds to a course phase component of the phase of the signal; and
performing the configuring the plurality of first capacitors based on the plurality of first coded digital signals representing the first amplitude of the signal using the first clock signal and performing the configuring the plurality of second capacitors based on the plurality of second coded digital signals representing the second amplitude of the signal using the second clock signal, and in accordance therewith, generating the signal having the phase on the common node.

21. The method of claim 20 wherein performing the configuring the plurality of first capacitors based on the plurality of first coded digital signals representing the first amplitude of the signal using the first clock signal comprises configuring a plurality of first switches coupled between the first capacitor terminals of the first capacitors and the two or more reference voltages, and wherein performing the configuring the plurality of second capacitors based on the plurality of second coded digital signals representing the second amplitude of the signal using the second clock signal comprises configuring a plurality of second switches coupled between the first capacitor terminals of the second capacitors and the two or more reference voltages.

22. The method of claim 21 wherein the first switches are configured before the second switches to couple a first phase component of the signal to the common node, wherein the second switches are configured after the first switches to couple a second phase component of the signal to the common node, and wherein a time difference between the configuration of the first switches and the configuration of the second switches corresponds to a time difference between the first clock phase and the second clock phase.

23. The method of claim 20 wherein the two more reference voltages comprise a first power supply voltage and ground.

24. The method of claim 20 wherein the two more reference voltages comprise a first power supply voltage, a second power supply voltage, and ground.

25. The method of claim 20 wherein the first clock signal and the second clock signal are differential clock signals.

26. The method of claim 20 wherein the first clock signal has a fifty percent duty cycle and the second clock signal has a fifty percent duty cycle.

27. The method of claim 20 wherein the plurality of different clock phases differ in phase by equal phase differences.

28. The method of claim 20 wherein the plurality of different clock phases comprise eight or more clock phases.

29. The method of claim 28 wherein a number of different clock phases is binary.

30. The method of claim 20 wherein the plurality of different clock phases comprise four clock phases, and wherein the plurality of first coded digital signals represent an in-phase component of the signal, and wherein the plurality of second coded digital signals represent a quadrature component of the signal.

31. The method of claim 30 wherein the plurality of clock signals having the plurality of different clock phases comprise an in-phase clock signal, a quadrature clock signal, an inverse of the in-phase clock signal, and an inverse of the quadrature clock signal.

32. A power amplifier circuit comprising:
a plurality of first capacitors having a plurality of first capacitor terminals configured between two or more reference voltages based on a plurality of first coded digital signals representing a first amplitude of a signal;
a plurality of second capacitors having a plurality of first capacitor terminals configured between two or more reference voltages based on a plurality of second coded digital signals representing a second amplitude of a signal, wherein a difference between the first amplitude and the second amplitude corresponds to a fine phase component of a phase of the signal, and wherein a plurality of second capacitor terminals of the first capacitors and a plurality of second capacitor terminals of the second capacitors are coupled to a common node;
a clock select circuit to select a first clock signal and a second clock signal from a plurality of clock signals, the plurality of clock signals having a plurality of different clock phases, wherein the first clock signal has a first clock phase and the second clock signal has a second clock phase and wherein the first clock phase is adjacent in phase to the second clock phase in the plurality of different clock phases, and wherein a difference between the first clock phase and the second clock phase corresponds to a course phase component of the phase of the signal; and
wherein the plurality of first capacitors are configured based on the plurality of first coded digital signals representing the first amplitude of the signal using the first clock signal and the plurality of second capacitors are configured based on the plurality of second coded digital signals representing the second amplitude of the signal using the second clock signal to generate the signal having the phase on the common node.

33. The circuit of claim 32 further comprising a plurality of switching circuits, wherein performing the configuring of the plurality of first capacitors based on the plurality of first coded digital signals representing the first amplitude of the signal using the first clock signal comprises configuring a plurality of first switches coupled between the first capacitor terminals of the first capacitors and the two or more reference voltages, and wherein performing the configuring of the plurality of second capacitors based on the plurality of second coded digital signals representing the second amplitude of the signal using the second clock signal comprises configuring a plurality of second switches coupled between the first capacitor terminals of the second capacitors and the two or more reference voltages.

34. The circuit of claim 33 wherein the first switches are configured before the second switches to couple a first phase component of the signal to the common node, wherein the second switches are configured after the first switches to couple a second phase component of the signal to the common node, and wherein a time difference between the configuration of the first switches and the configuration of the second switches corresponds to a time difference between the first clock phase and the second clock phase.

35. The circuit of claim 32 wherein the two more reference voltages comprise a first power supply voltage and ground.

36. The circuit of claim 32 wherein the two more reference voltages comprise a first power supply voltage, a second power supply voltage, and ground.

37. The circuit of claim 32 wherein the first clock signal and the second clock signal are differential clock signals.

38. The circuit of claim 32 wherein the first clock signal has a fifty percent duty cycle and the second clock signal has a fifty percent duty cycle.

39. The circuit of claim 32 wherein the plurality of different clock phases differ in phase by equal phase differences.

40. The circuit of claim 32 wherein the plurality of different clock phases comprise eight or more clock phases.

41. The circuit of claim 40 wherein a number of different clock phases is binary.

42. The circuit of claim 32 wherein the plurality of different clock phases comprise four clock phases, and wherein the plurality of first coded digital signals represent an in-phase component of the signal, and wherein the plurality of second coded digital signals represent a quadrature component of the signal.

43. The circuit of claim 42 wherein the plurality of clock signals having the plurality of different clock phases comprise an in-phase clock signal, a quadrature clock signal, an inverse of the in-phase clock signal, and an inverse of the quadrature clock signal.
